(19) United States
(12) Patent Application Publication
(10) Pub. No.: US 2007/0148905 A1
(43) Pub. Date: Jun. 28, 2007

(54) METHOD OF FORMING A TRENCH ISOLATION LAYER IN A SEMICONDUCTOR DEVICE

(76) Inventor: Seung Soon Jang, Gyeonggi-do (KR)

Correspondence Address: SHERR & NOURSE, PLLC, 620 HERNDON PARKWAY, SUITE 200, HERNDON, VA, 20170, US

(21) Appl. No.: 11/616,758

(22) Filed: Dec. 27, 2006

(30) Foreign Application Priority Data
Dec. 28, 2005 (KR) 10-2005-0132088

(51) Int. Cl. H01L 21/76

(52) U.S. Cl. 438/424

(57) ABSTRACT

Embodiments relate to a method of forming a trench isolation layer in a semiconductor device. In embodiments, the method may include sequentially stacking a pad oxide layer and a pad nitride layer having a first thickness on a semiconductor substrate, forming a pad oxide pattern and a pad nitride pattern, which expose a surface of an isolation layer of the semiconductor substrate, by patterning the pad oxide layer and the pad nitride layer, forming a trench by etching the isolation layer of the semiconductor substrate to a prescribed depth, forming a sidewall oxide layer on an inner wall of the trench, and forming a trench isolation layer by depositing a buried insulating layer filling the trench formed with the sidewall oxide layer, removing the pad nitride pattern by a prescribed thickness through a moat wet etch such that a residual nitride pattern having a second thickness remains on the pad oxide pattern, removing particles generated during the moat wet etch by performing wet cleaning with respect to the residual nitride pattern, and depositing an insulating layer, which is used as a hard mask layer together with the residual nitride pattern, on the residual nitride pattern.

The present application claims priority under 35 U.S.C. 119 and 35 U.S.C. 365 to Korean Patent Application No. 10-2005-0132088 (filed on Dec. 28, 2005), which is hereby incorporated by reference in its entirety.

### BACKGROUND

As semiconductor devices become more highly integrated, an isolation distance between devices may become shortened. Accordingly, certain micro-sized devices may not be properly isolated through typical isolation methods, such as local oxidation of silicon (LOCOS). To isolate certain micro-sized devices, a trench isolation process may be used. In the trench isolation process, a trench may be formed on a semiconductor substrate, and an insulating material such as a silicon oxide material may be filled in the trench, which may provide device isolation.

Referring to FIG. 1, pad oxide layer 110 and pad nitride layer 120 may be sequentially formed on semiconductor substrate 100 having an isolation area and an active area.

Referring to FIG. 2, pad oxide layer 110 and pad nitride layer 120 may be patterned, and may form pad oxide layer pattern 112 and pad nitride pattern 122. A portion of the surface of the isolation area in semiconductor substrate 100 may thus be exposed. The isolation area of semiconductor substrate 100 may be etched to a prescribed depth by using pad oxide layer pattern 112 and pad nitride pattern 122 as an etching mask, thereby forming trench 130.

Sidewall oxide layer 140 may be formed in trench 130. Trench 130 may then be filled with a buried insulating layer, which may form isolation layer 150. A planarization process may then be performed with respect to a resultant structure such that an upper surface of pad nitride pattern 122 may be exposed.

Referring to FIG. 3, a moat wet etch process may be performed to remove pad nitride pattern 122. Thus, the surface of pad oxide pattern 112 may be exposed. At the same time, particles 160 in the form of an oxide layer may be generated on the exposed surface of pad oxide pattern 112 through the moat wet etch process.

Referring to FIG. 4, nitride layer 171 and TEOS oxide layer 172 may be sequentially stacked on a surface of the resultant structure, and may form hard mask layer 170. Hard mask layer 170 may be used in subsequent processes.

In the related art trench isolation layer, particles 160 shown in FIG. 3 may be removed from the surface of pad oxide layer pattern 112. However, since a thickness of pad oxide layer pattern 112 may be approximately 150 Å, it may be difficult to perform HF cleaning to remove particles 160 in the form of an oxide layer. Accordingly, particles 160 may continuously remain during subsequent processes. This may degrade a stability of a semiconductor device.

### SUMMARY OF THE INVENTION

Embodiments relate to a method for fabricating a semiconductor device. Embodiments relate to a method for forming a trench isolation layer in a semiconductor device, capable of removing particles during a moat wet etch process.

Embodiments relate to a trench isolation layer of a semiconductor device that may be capable of removing particles in the form of an oxide layer generated through a moat wet etch process.

Embodiments, a method for forming a trench isolation layer may include sequentially stacking a pad oxide layer and a pad nitride layer having a first thickness on a semiconductor substrate, forming a pad oxide pattern and a pad nitride pattern, which expose a surface of an isolation layer of the semiconductor substrate, by patterning the pad oxide layer and the pad nitride layer, forming a trench by etching the isolation layer of the semiconductor substrate to a prescribed depth, forming a sidewall oxide layer on an inner wall of the trench, and forming a trench isolation layer by depositing a buried insulating layer filling the trench formed with the sidewall oxide layer, removing the pad nitride pattern by a prescribed thickness through a moat wet etch such that a residual nitride pattern having a second thickness remains on the pad oxide pattern, removing particles generated during the moat wet etch by performing wet cleaning with respect to the residual nitride pattern, and depositing an insulating layer, which may be used as a hard mask layer together with the residual nitride pattern, on the residual nitride pattern.

In embodiments, a thickness of the pad nitride pattern removed through the moat wet etch may be 50 Å or less. In embodiments, a second thickness of the residual nitride pattern may be in a range of 300 Å to 500 Å.

In embodiments, a moat wet etch may be performed such that a thickness of a lost upper part of the trench isolation layer is 150 Å or less. In embodiments, a wet cleaning may be performed by using an HF cleaning solution.

### BRIEF DESCRIPTION OF THE DRAWINGS

FIGS. 1 to 4 are example sectional views illustrating a related art method for forming a trench isolation layer of a semiconductor device; and

FIGS. 5 to 8 are example sectional views illustrating a method for forming a trench isolation layer of a semiconductor device according to embodiments.

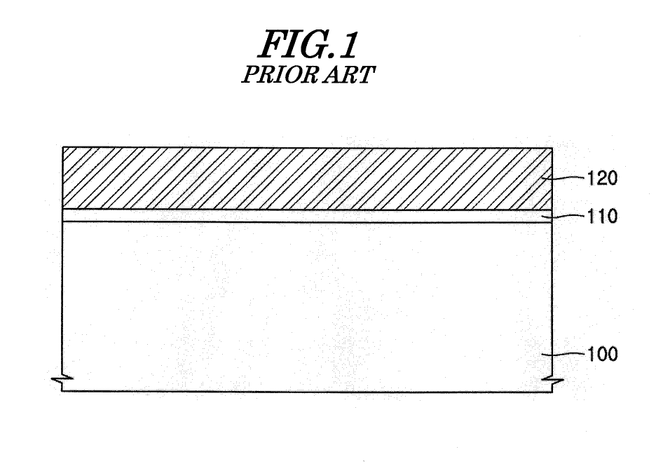

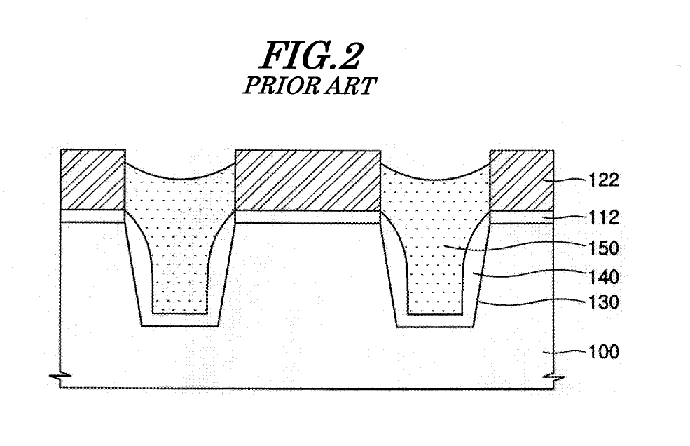

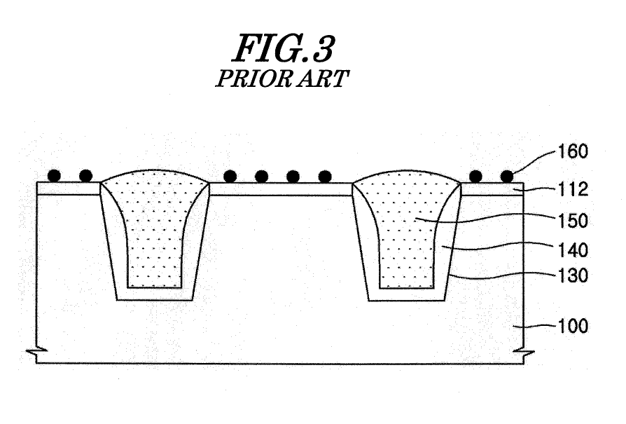

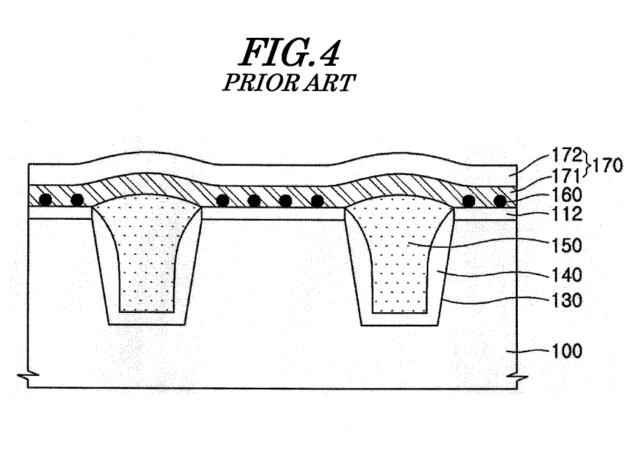

### DETAILED DESCRIPTION OF EMBODIMENTS

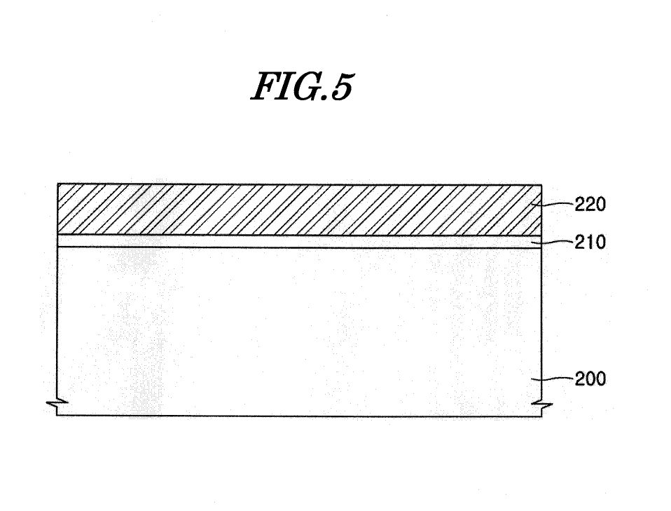

Referring to FIG. 5, pad oxide layer 210 and pad nitride layer 220 may be sequentially formed on semiconductor substrate 200. Semiconductor substrate 200 may have an isolation area and an active area defined by the isolation layer. A trench isolation layer may be formed on the isolation layer through a subsequent process, and various devices, such as a transistor, may be formed on the active area.

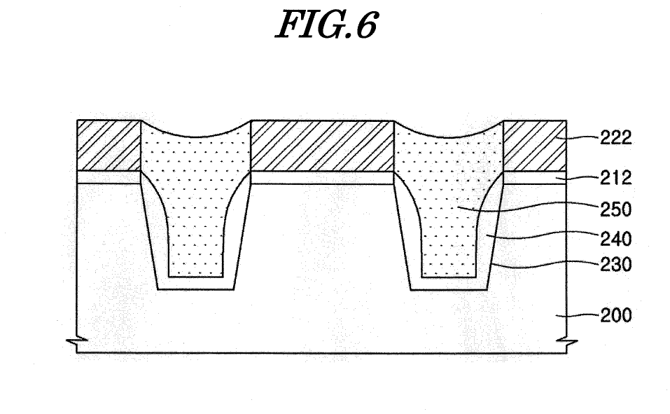

Referring to FIG. 6, pad oxide layer 210 and pad nitride layer 220 may be patterned, thereby forming pad oxide layer pattern 212 and pad nitride pattern 222. A portion of the surface of an isolation area in semiconductor substrate 200 may thus be exposed. The isolation area of semiconductor substrate 200 may be etched to a prescribed depth, for example using the pad oxide layer pattern and the pad nitride pattern as an etching mask. This may form trench 230.

Sidewall oxide layer 240 may be formed in trench 230. Trench 230 may then be filled with a buried insulating layer, which may form trench isolation layer 250. Thereafter, a planarization process may be performed with respect to a resultant structure such that an upper surface of the pad nitride pattern may be exposed.

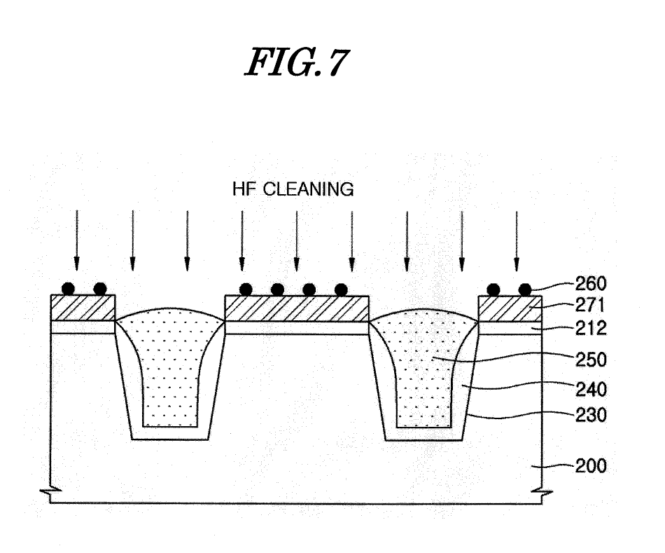

Referring to FIG. 7, pad nitride pattern 222 may be removed by a prescribed thickness through a moat wet etch process. Residual nitride layer pattern 271 may thus be formed. A thickness of pad nitride pattern 222 removed through the moat wet etch process may be approximately 50 Å or less. Accordingly, a thickness of residual pad nitride pattern 271 may be in the range of approximately 300 Å to 500 Å.

A cleaning process, for example using an HF cleaning solution, may be performed as indicated by the arrows illustrated in FIG. 7. The cleaning may be performed with respect to particles 260. This may remove small-sized particles 260, which may have the form of an oxide layer, and which may have been generated on residual nitride pattern 271 through the moat wet etch process.

Since a pad oxide layer pattern having a relatively small thickness may be exposed through the moat wet process, there may be limitations with respect to the wet cleaning process. According to embodiments, pad nitride layer pattern 222 may not be completely removed, and the nitride layer pattern may remain at a prescribed thickness. Accordingly, remaining nitride layer pattern 271 may cover pad oxide layer pattern 212. It may therefore be possible to perform HF wet cleaning to remove particles without affecting pad oxide pattern 212. In embodiments, an upper part of trench isolation layer 250 may be lost by a prescribed thickness through the HF cleaning, and the thickness of the lost trench isolation layer may be approximately 150 Å or less.

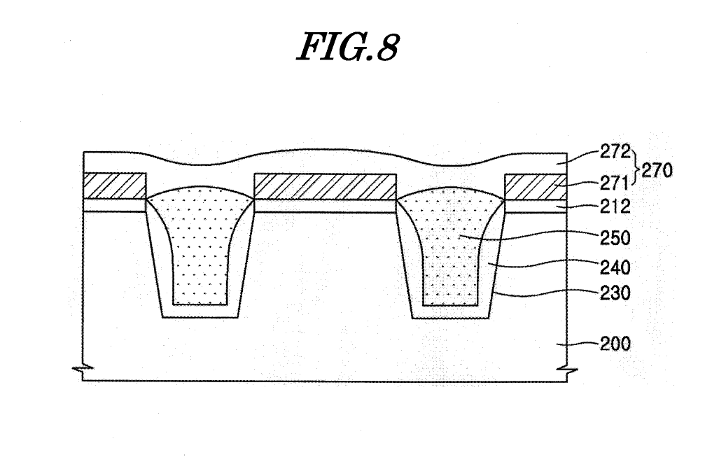

Referring to FIG. 8, an insulating layer, such as TEOS oxide layer 272, may be formed on residual nitride layer pattern 271, on which particles 260 may be removed through the HF cleaning. TEOS oxide layer 272 may form hard mask layer 270, which may be used in a subsequent process with residual nitride pattern 271.

In embodiments, a pad nitride pattern may remain with a prescribed thickness during a moat wet etch, so it may be possible to perform a wet cleaning to remove particles in the form of an oxide layer generated after the moat wet etch process. In addition, it may be possible to use the residual pad nitride pattern as a hard mask layer in a subsequent process.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method comprising:
forming a pad oxide pattern over a semiconductor substrate and a pad nitride pattern over the pad oxide pattern, the pad nitride pattern having a first thickness;
forming a trench isolation layer in the semiconductor substrate;
removing a prescribed thickness of the pad nitride pattern through a moat wet etch such that a residual nitride pattern having a second thickness remains over the pad oxide pattern;
performing a wet cleaning of the residual nitride pattern; and
depositing an insulating layer on the residual nitride pattern.

2. The method of claim 1, further comprising:
sequentially stacking a pad oxide layer and a pad nitride layer having the first thickness over the semiconductor substrate;
patterning the pad oxide layer and the pad nitride layer to form the pad oxide pattern and the pad nitride pattern and to expose a surface of an isolation layer of the semiconductor substrate;
forming a trench by etching the isolation layer of the semiconductor substrate to a prescribed depth;
forming a sidewall oxide layer on an inner wall of the trench; and
forming the trench isolation layer by depositing a buried insulating layer in the trench over the sidewall oxide layer.

3. The method of claim 1, wherein the insulating layer comprises a TEOS oxide layer.

4. The method of claim 1, wherein the insulating layer and the residual nitride pattern comprise a hard mask.

5. The method of claim 1, wherein the wet cleaning of the residual nitride pattern is performed to remove particles generated during the moat wet etch.

6. The method of claim 1, wherein the thickness removed from the pad nitride pattern through the moat wet etch is 50 Å or less.

7. The method of claim 1, wherein the second thickness of the residual nitride pattern is in a range of 300 Å to 500 Å.

8. The method of claim 1, wherein a thickness of an upper part of the trench isolation layer removed by the moat wet etch is 150 Å or less.

9. The method of claim 1, wherein the wet cleaning is performed using an HF cleaning solution.

10. A device, comprising:
a pad oxide layer pattern formed over a semiconductor substrate;
a pad nitride layer having a first thickness formed over the pad oxide layer;
a trench isolation layer formed in the semiconductor substrate; and
an insulating layer formed over the pad nitride layer and the trench isolation layer, wherein prior to forming the insulating layer a cleaning process is performed in which the pad nitride pattern is reduced from a second thickness to the first thickness through a moat wet etch, and a wet cleaning is performed on the pad nitride layer after the moat wet etch.

11. The device of claim 10, wherein the wet cleaning removes particles generated during the moat wet etch process.

12. The device of claim 11, wherein the first thickness is in a range of 300 Å to 500 Å.

13. The device of claim 10, wherein the insulating layer comprises a TEOS oxide layer, and wherein the TEOS oxide layer and the pad nitride layer comprise a hard mask layer.

14. The device of claim 10, wherein the trench isolation layer comprises a trench formed in the semiconductor substrate having a prescribed depth, a sidewall oxide layer on an inner wall of the trench, and an insulating layer in a trench formed over the sidewall oxide layer.

15. A method for forming a trench isolation layer, comprising:
sequentially stacking a pad oxide layer and a pad nitride layer having a first thickness on a semiconductor substrate;
forming a pad oxide pattern and a pad nitride pattern, which expose a surface of an isolation layer of the semiconductor substrate, by patterning the pad oxide layer and the pad nitride layer;
forming a trench by etching the isolation layer of the semiconductor substrate to a prescribed depth;
forming a sidewall oxide layer on an inner wall of the trench;
forming a trench isolation layer by depositing a buried insulating layer filling the trench, formed over the sidewall oxide layer;
removing the pad nitride pattern by a prescribed thickness through a moat wet etch such that a residual nitride pattern having a second thickness remains on the pad oxide pattern;
removing particles generated during the moat wet etch by performing wet cleaning with respect to the residual nitride pattern; and
depositing an insulating layer on the residual nitride pattern.

16. The method of claim 15, wherein the second thickness of the residual nitride pattern is in a range of 300 Å to 500 Å.

17. The method of claim 15, wherein the insulating layer comprises a TEOS oxide layer, and wherein the TEOS oxide layer and the pad nitride layer comprise a hard mask layer.
